(19) United States
(12) Patent Application Publication
(10) Pub. No.: US 2026/0196274 A1
(43) Pub. Date: Jul. 9, 2026

(54) STORAGE DEVICE

(71) Applicant: Kioxia Corporation, Tokyo (JP)

(72) Inventors: Hiroshi MAEJIMA, Tokyo (JP); Toshifumi HASHIMOTO, Fujisawa (JP); Yoshinao SUZUKI, Yokohama (JP); Katsuaki ISOBE, Yokohama (JP)

(73) Assignee: Kioxia Corporation, Tokyo (JP)

(21) Appl. No.: 19/314,037

(22) Filed: Aug. 29, 2025

(30) Foreign Application Priority Data
Jan. 9, 2025 (JP) 2025-003508

(51) Int. Cl. G11C 16/28; G11C 16/08; G11C 16/32

(52) U.S. Cl. CPC G11C 16/28; G11C 16/08; G11C 16/32

(57) ABSTRACT

A storage device includes a bit line, a source line, a first cell transistor between the bit line and the source line, a second cell transistor between the first cell transistor and the bit line, a third cell transistor between the first cell transistor and the source line, first to third word lines being connected to gates of the first to third cell transistors, respectively. During a first period, a first voltage is applied to the source line, a second voltage is applied to at least one of the second word line and the third word line, and a third voltage is applied to the first word line. The first word line reaches the third voltage after the second or third word line reaches the second voltage. The second and third voltages are both equal to or more than threshold voltages of the first, second, and third cell transistors.

### CROSS-REFERENCE TO RELATED APPLICATION

This application is based upon and claims the benefit of priority from Japanese Patent Application No. 2025-003508, filed Jan. 9, 2025, the entire contents of which are incorporated herein by reference.

### FIELD

Embodiments described herein relate generally to a storage device.

### BACKGROUND

Storage devices are required to operate at high speed.

### BRIEF DESCRIPTION OF THE DRAWINGS

FIG. 1 is a block diagram of a storage device in a first embodiment.

FIG. 2 is a circuit diagram of one block of the storage device in the first embodiment.

FIG. 3 schematically illustrates an example of the structure of a part of a memory cell array of the storage device in the first embodiment.

FIG. 4 illustrates components of a row decoder of the storage device in the first embodiment and connection between the components.

FIG. 5 illustrates components of a driver of the storage device in the first embodiment and connection between the components.

FIG. 6 illustrates classification of driver circuits in the storage device in the first embodiment.

FIG. 7 illustrates components of a part of the driver of the storage device in the first embodiment and connection between the components.

FIG. 8 illustrates distribution of threshold voltages of cell transistors storing 3-bit data of the storage device in the first embodiment and an example of mapping of data.

FIG. 9 illustrates one state of the driver during data reading of the storage device in the first embodiment.

FIG. 10 illustrates the potential of some wires during data reading of the storage device in the first embodiment along a time axis.

FIG. 11 illustrates an overview of a write operation in the storage device in the first embodiment along a time axis.

FIG. 12 illustrates the order of data writing in the storage device in the first embodiment.

FIG. 13 illustrates the potentials of some nodes during verifying in the storage device in the first embodiment along a time axis.

FIG. 14 illustrates the potentials of some nodes during verifying in the storage device in the first embodiment along a time axis.

FIG. 15 illustrates the potentials of some nodes during verifying in the storage device in the first embodiment along a time axis.

FIG. 16 illustrates the components of a voltage generation circuit of a storage device in a second embodiment and an example of connection.

FIG. 17 illustrates the potential of some wires during data reading of the storage device in the second embodiment along a time axis.

### DETAILED DESCRIPTION

A storage device capable of operating at high speed is provided.

In general, according to one embodiment, a storage device includes a bit line, a source line, a first cell transistor between the bit line and the source line, a second cell transistor between the first cell transistor and the bit line, a third cell transistor between the first cell transistor and the source line, a first word line connected to a gate of the first cell transistor, a second word line connected to a gate of the second cell transistor, and a third word line connected to a gate of the third the cell transistor. A first voltage is applied to the source line over a first period. A second voltage equal to or more than threshold voltages of the first, second, and third cell transistors is applied to at least one of the second word line and the third word line at a first time during the first period. A third voltage equal to or more than the threshold voltages of the first, second, and third cell transistors is applied to the first word line at a second time after the first time during the first period.

Embodiments will be described below with reference to the drawings. An additional number or character may be added to the end of reference numerals of a plurality of components having the substantially same functions and configurations in a certain embodiment or different embodiments, so as to distinguish between the components. In an embodiment following an embodiment that has already been described, differences from the already described embodiment will be mainly described. All descriptions of a certain embodiment also apply as descriptions of another embodiment, unless explicitly or obviously excluded.

Each functional block can be realized as either hardware or computer software, or a combination of both. It is not essential that each functional block is distinguished as in the following examples. A part of functions may be performed by a functional block other than an illustrated functional block, or may be divided into smaller functional subblocks.

In this description and the claims, when a certain first element is “connected” to another second element, it includes that the first element is connected to the second element directly or always or via a selectively conductive element.

Hereinafter, embodiments will be described by using a three-dimensional orthogonal coordinate system. The orientation of an x-axis is called an X direction. The orientation opposite to the X direction is called a −X direction. The orientation of a y-axis is called a Y direction. The orientation opposite to the Y direction is called a −Y direction. The orientation of a z-axis is called a Z direction, and an upper direction represents the Z direction. The orientation opposite to the Z direction is called a −Z direction.

### 1. First Embodiment

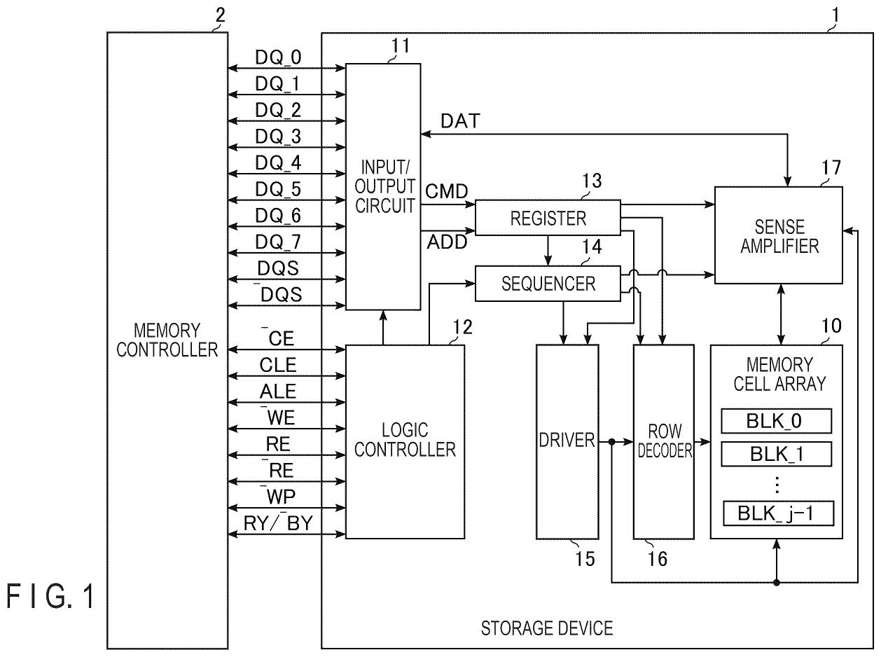

FIG. 1 is a block diagram of a storage device in a first embodiment. The storage device 1 is a device that stores data by using memory cells. The storage device 1 operates based on a command CMD and address information ADD that are received from a memory controller 2. The storage device 1 receives data DAT to be written, and outputs data stored in the storage device 1.

The storage device 1 includes components such as a memory cell array 10, an input/output circuit 11, a logic controller 12, a register 13, a sequencer 14, a driver 15, a row decoder 16, and a sense amplifier 17.

The memory cell array 10 is a collection of arranged memory cells. The memory cell array 10 includes j (j is a positive integer) memory blocks (blocks) BLK. Each block BLK includes a plurality of cell transistors MT. Each cell transistor MT functions as one memory cell. In the region in which the memory cell array 10 is provided, wires such as word lines WL (not illustrated) and bit lines BL (not illustrated) are also arranged.

The input/output circuit 11 transmits and receives various signals to and from the memory controller 2. The input/output circuit 11 transmits and receives input/output signals DQ_0, DQ_1, DQ_2, DQ_3, DQ_4, DQ_5, DQ_6, and DQ_7, and signals DQS and ⁻DQS. The symbol “⁻” indicates the inverted logic of the logic of a signal whose name is without the symbol “⁻”, and indicates that the signal whose name follows the symbol “⁻” has a valid logic (or is asserted) when it is at a low (“L”) level. The set of the input/output signals DQ_0 to DQ_7 sends a command (CMD), write data or lead data (DAT), address information (ADD), and a status (STA). The signals DQS and ⁻DQS indicate the timings of taking in the input/output signals DQ_0 to DQ_7.

The logic controller 12 transmits and receives signals to and from the memory controllers 2. The logic controller 12 transmits and receives signals ⁻CE, CLE, ALE, ⁻WE, RE, ⁻RE, ⁻WP, and RY/BY. The signal ⁻CE enables the storage device 1. The signal CLE notifies the storage device 1 of transmission of a command by the input/output signal DQ. The signal ALE notifies the storage device 1 of transmission of address information ADD by the input/output signal DQ. The signal ⁻WE instructs the storage device 1 to take in the input/output signal DQ. The signal-RE instructs the storage device 1 to output the input/output signal DQ. The ready/busy signal RY/BY indicates whether the storage device 1 is in a ready state or a busy state, and indicates the busy state with a low level. When the storage device 1 is in the ready state, a command is received, and when in the busy state, a command is not received.

The register 13 is a circuit that holds the command CMD and the address information ADD that are received by the storage device 1. The command CMD instructs the sequencer 14 to perform various operations including data reading, data writing, and data erasing. In an example, the address information ADD includes a block address, a page address, and a column address. The block address, the page address, and the column address specify a block BLK, a word line WL, and a bit line BL, respectively.

The sequencer 14 is a circuit that controls the operation of the entire storage device 1. Based on the command CMD received from the register 13, the sequencer 14 controls the driver 15, the row decoder 16, and the sense amplifier 17 to perform various operations including data reading, data writing, and data erasing.

The driver 15 is a circuit that applies, to several components, various voltages required for the operation of the storage device 1. The driver 15 receives a power supply voltage from the memory controller 2, and generates a plurality of voltages from the power supply voltage. The driver 15 supplies the generated voltages to the memory cell array 10, the row decoder 16, and the sense amplifier 17.

The row decoder 16 is a circuit for selecting the blocks BLK. The row decoder 16 transfers the voltage supplied from the driver 15 to one block BLK that is selected based on the block address received from the register 13.

The sense amplifier 17 is a circuit that outputs a signal based on data stored in the memory cell array 10. The sense amplifier 17 senses the state of a cell transistor MT, and generates read data based on the sensed state. The sense amplifier 17 applies a voltage based on write data to the bit line BL.

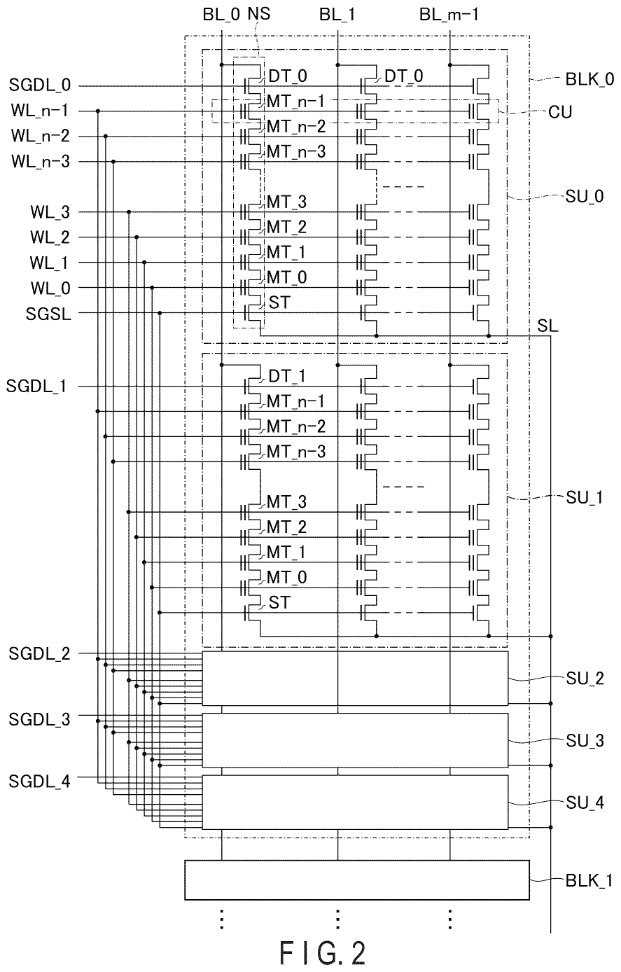

FIG. 2 is a circuit diagram of one block of the storage device in the first embodiment. A plurality of blocks BLK, for example, all the blocks BLK, include the components and connection illustrated in FIG. 2.

One block BLK includes a plurality of string units SU. FIG. 2 illustrates an example of five string units SU_0 to SU_4.

As illustrated in FIG. 2, each of m bit lines BL_0 to BL_m−1 is connected to one NAND string NS from each of the string units SU_0 to SU_4 in each block BLK. m is a positive integer.

Each NAND string NS includes one select gate transistor ST, n cell transistors MT (MT_0 to MT_n−1), and one select gate transistor DT (DT_0, DT_1, DT_2, DT_3, or DT_4). n is a positive integer. The cell transistors MT are elements that function as memory cells, and store data in a non-volatile manner. Each cell transistor MT includes a control gate electrode or a gate electrode (word line WL), and a charge storage film insulated from the surroundings, and stores data in a non-volatile manner based on the charge in the charge storage film. Data is written to the cell transistor MT by injecting electrons to the charge storage film.

The select gate transistor ST, the cell transistors MT_0 to MT_n−1, and the select gate transistor DT are connected in series between a source line SL and one bit line BL in this order.

A plurality of NAND strings NS, which are connected to the plurality of different bit lines BL, respectively, constitute one string unit SU. In each string unit SU, the control gate electrodes of the cell transistors MT_0 to MT_n−1 are connected to word lines WL_0 to WL_n−1, respectively. A set of cell transistors MT that share a word line WL in one string unit SU is called a cell unit CU.

The select gate transistors DT_0 to DT_4 belong to string units SU_0 to SU_4, respectively. In FIG. 2, illustration of the select gate transistors DT_2, DT_3, and DT_4 is omitted. The gate of each select gate transistor DT0 of the plurality of NAND strings NS of the string unit SU_0 is connected to a select gate line SGDL_0. Similarly, the gates of the select gate transistors DT_1, DT_2, DT_3, and DT_4 of the plurality of NAND strings NS of the string units SU_1, SU_2, SU_3, and SU_4 are connected to the select gate lines SGDL_1, SGDL_2, SGDL_3, and SGDL_4, respectively.

The gate of the select gate transistor ST is connected to the select gate line SGSL.

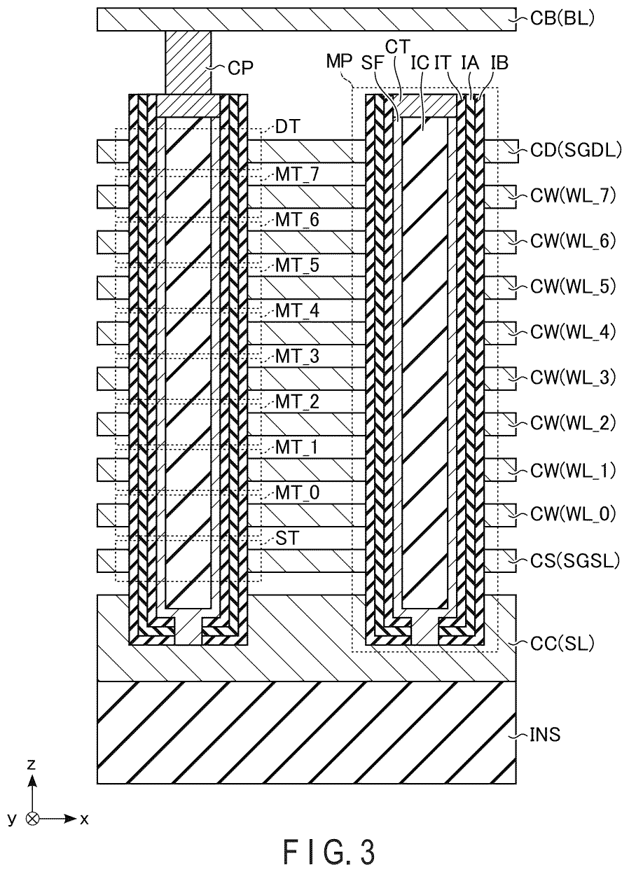

As long as the circuit illustrated in FIG. 2 is realized, each block BLK may have any kind of structure. As an example, each block BLK can have the structure illustrated in FIG. 3. FIG. 3 schematically illustrates an example of the structure of a part of the memory cell array of the storage device of the first embodiment.

As illustrated in FIG. 3, an insulator INS is provided. A conductor CC is provided on an upper surface of the insulator INS. The conductor CC functions as a part of the source line SL. FIG. 3 is based on an example in which n is 8.

One conductor CS, n, that is, eight conductors CW, and a conductor CD are provided above the conductor CC. The conductors CS, CW, and CD are arranged in this order along a z-axis at intervals, and extend along a y-axis. The conductors CS, CW, and CD function as the select gate line SGSL, the word lines WL_0 to WL_7, and the select gate line SGDL of each NAND string NS, respectively.

A memory pillar MP is provided above the conductor CC. The memory pillar MP penetrates the conductors CS, CW, and CD. A bottom surface of the memory pillar MP is located in the conductor CC. The memory pillar MP includes an insulator IC, a semiconductor (layer) SF, a tunnel insulator (layer) IT, a charge storage film IA, a block insulator (layer) IB, and a conductor (layer) CT.

The insulator IC has a columnar shape extending along the z-axis, and is located at the center of the memory pillar MP. The semiconductor SF covers side surfaces of the insulator IC. The semiconductor SF is in contact with the conductor CC at a part of a bottom surface. The semiconductor SF functions as channel regions and bodies of the cell transistors MT and the select gate transistors DT and ST. The channel regions are regions in which channels are formed.

The tunnel insulator IT covers side surfaces of the semiconductor SF. The charge storage film IA is an insulator or a conductor, and covers side surfaces of the tunnel insulator IT. The block insulator IB covers side surfaces of the tunnel insulator IT.

The conductor CT covers an upper surface of the insulator IC and an upper surface of the semiconductor SF.

The upper surfaces of some conductors CT are connected to the conductors CB via conductive plugs CP. The conductors CB extend along the x-axis, and are arranged along the y-axis. The conductors CB function as bit lines BL.

The portions of each memory pillar MP that intersect the conductors CS, CW, and CD function as the select gate transistor ST, the cell transistors MT, and the select gate transistor DT, respectively.

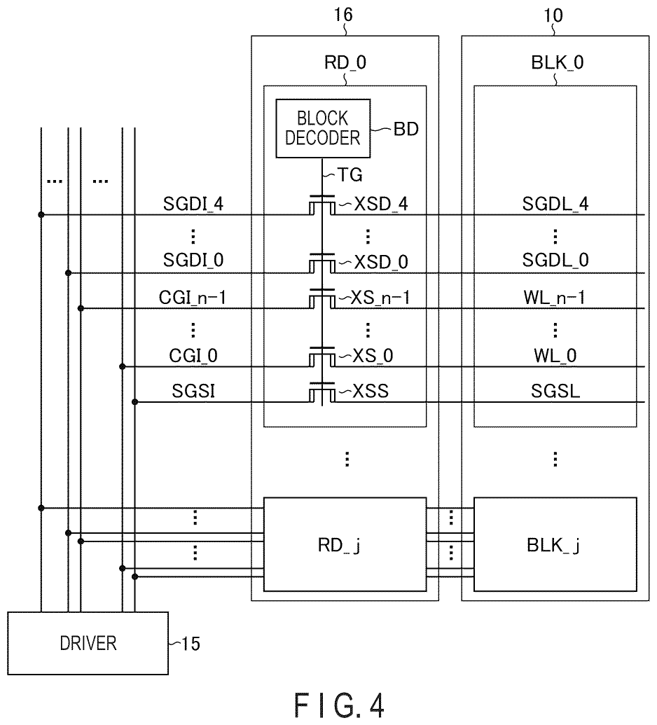

FIG. 4 illustrates components of the row decoder of the storage device in the first embodiment and connection between the components. As illustrated in FIG. 4, the row decoder 16 includes j row decoder circuits RD_0 to RD_j−1.

The row decoder circuits RD_0 to RD_j−1 are connected to blocks BLK_0 to BLK_j−1, respectively. The row decoder circuit RD places the block BLK connected to the row decoder circuit RD itself in a selected state. The row decoder circuit RD includes a block decoder BD, transistors XSD_0 to XSD_4, the number of which is the same as the number of the string units SU in one block BLK, n transistors XS_0 to XS_n−1, and a transistor XSS.

The block decoder BD decodes the information (block address information) indicating a block address. The block decoder BD is connected to the transistors XSD_0 to XSD_4, the transistors XS_0 to XS_n−1, and a gate of the transistor XSS by a wire TG. When the block address information indicates the block BLK connected to the row decoder circuit RD in which the block decoder BD is included, the block decoder BD applies a high-level voltage to the wire TG. The high-level voltage has a magnitude that enables the transistors XSD_0 to XSD_4, the transistors XS_0 to XS_n−1, and the transistor XSS to apply the voltage that they receive at one end to the other end.

In an example, the transistor XSD_0 to XSD_4, the transistors XS_0 to XS_n−1, and the transistor XSS are MOSFETs (Metal Oxide Semiconductor Field Effect Transistors). Hereinafter, one of the source and drain of a certain transistor may be referred to as a first end, and the other of the source and drain of this transistor may be referred to as a second end. The transistors XSD_0 to XSD_4 are connected to wires SGDI_0 to SGDI_4 at respective first ends, respectively. The transistors XSD_0 to XSD_4 are connected to the select gate lines SGDL_0 to SGDL_4 at second ends, respectively.

The transistors XS_0 to XS_n−1 are connected to wires CGI_0 to CGI_n−1 at respective first ends, respectively. The transistors XS_0 to XS_n−1 are connected to word lines WL_0 to WL_n−1 at respective second ends, respectively.

The transistor XSS is connected between a wire SGSI and the select gate line SGSL.

The driver 15 applies a voltage to the wires SGDI_0 to SGDI_4, the CGI_0 to CGI_n−1, and the SGSI.

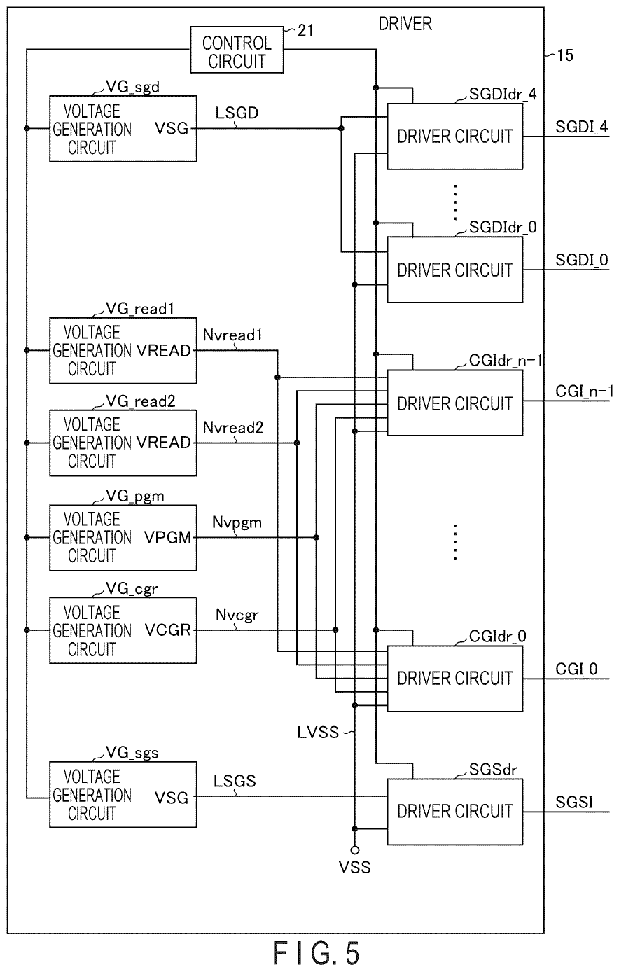

FIG. 5 illustrates components of the driver of the storage device in the first embodiment and connection between the components. As illustrated in FIG. 5, the driver 15 includes voltage generation circuits VG_sgd, VG_read1, VG_read2, VG_pgm, VG_cgr, and VG_sgs, driver circuits SGDIdr_0 to SGDIdr_4, CGIdr_0 to CGIdr_n−1 and SGSdr, and a control circuit 21.

The voltage generation circuit VG_sgd applies a voltage VSG to a wire LGSD. The voltage VSG is used in data reading. In an example, the voltage generation circuit VG_sgd generates the voltage VSG from a power supply voltage VDD. In an example, the voltage VSG has a fixed magnitude.

The voltage generation circuit VG_read1 applies a voltage VREAD to a wire Nvread1. The voltage VREAD is used in data reading. In an example, the voltage generation circuit VG_read1 generates the voltage VREAD from the power supply voltage VDD. In an example, the voltage VREAD has a fixed magnitude.

The voltage generation circuit VG_read2 applies the voltage VREAD to a wire Nvread2. The voltage VREAD is used in data reading. In an example, the voltage generation circuit VG_read2 generates the voltage VREAD from the power supply voltage VDD. In an example, the voltage VREAD has the fixed magnitude.

The voltage generation circuit VG_pgm applies a program voltage VPGM to a wire Nvpgm. The program voltage VPGM is used in data writing. In an example, the voltage generation circuit VG_pgm generates the program voltage VPGM from the power supply voltage VDD. The program voltage VPGM has a variable magnitude. The program voltage VPGM is a high voltage capable of increasing the threshold voltage of a select cell transistor MTsel. The select cell transistor MTsel is a cell transistor MT to which data is to be written and from which data is to be read.

The voltage generation circuit VG_cgr applies a read voltage VCGR to a wire Nvcgr. The read voltage VCGR is used in data reading. In an example, the voltage generation circuit VG_cgr generates the read voltage VCGR from the power supply voltage VDD. The read voltage VCGR has a variable magnitude.

The voltage generation circuit VG_sgs applies a voltage VSG to a wire LSGS. The voltage VSG is used in data reading. In an example, the voltage generation circuit VG_sgs generates the voltage VSG from the power supply voltage VDD.

The driver circuit SGDIdr_0 is connected to wires LSGD and LVSS. In addition, the driver circuit SGDIdr_0 is connected to a wire SGDI_0. The wire LVSS receives a ground voltage (or a reference voltage) VSS. The driver circuit SGDIdr_0 transfers one of the voltages applied to the wires LSGD and LVSS, respectively, which is dynamically selected, to the wire SGDI_0. The voltage applied to the wire SGDI_0 is selected by control of the control circuit 21.

Similarly, each of the driver circuits SGDIdr_1 to SGDIdr_4 is connected to the wires LSGD and LVSS. In addition, the driver circuits SGDIdr_1 to SGDIdr_4 are connected to the wires SGDI_1 to SGDI_4, respectively. The driver circuits SGDIdr_1 to SGDIdr_4 transfer one of the voltages applied to the wires LSGD and LVSS, respectively, which is dynamically selected, to the wires SGDI_1 to SGDI_4, respectively. The voltage applied to the wires SGDI_1 to SGDI_4 is selected by control of the control circuit 21.

The driver circuit CGIdr_0 is connected to the wires Nvread1, Nvread2, Nvpgm, Nvcgr, and LVSS. In addition, the driver circuit CGIdr_0 is connected to the wire CGI_0. The driver circuit CGIdr_0 transfers (or applies) one of the voltages applied to the wires Nvread1, Nvread2, Nvpgm, Nvcgr, and LVSS, respectively, which is dynamically selected, to the wire CGI_0. The voltage applied to the wire CGI_0 is selected by control of the control circuit 21.

Similarly, the driver circuits CGIdr_1 to CGIdr_n−1 are connected to the wires Nvread1, Nvread2, Nvpgm, Nvcgr, and LVSS. In addition, the driver circuits CGIdr_1 to CGIdr_n−1 are connected to the wires CGI_1 to CGI_n−1, respectively. The driver circuits CGIdr_1 to CGIdr_n−1 transfer one of the voltages applied to the wires Nvread1, Nvread2, Nvpgm, Nvcgr, and LVSS, respectively, which is dynamically selected, to the wires CGI_1 to CGI_n−1, respectively. The voltage applied to the wires CGI_1 to CGI_n−1 is selected by control of the control circuit 21.

The driver circuit SGSdr is connected to the wires LSGS and LVSS. The driver circuit SGSdr is connected to the wire SGSI. The driver circuit SGSdr transfers one of the voltages applied to the wires LSGS and LVSS, respectively, which is dynamically selected, to the wire SGSI. The voltage applied to the wire SGSI is selected by control of the control circuit 21.

The control circuit 21 controls the timing of outputting the voltage VSG by the voltage generation circuit VG_sgd. The control circuit 21 controls the timing of outputting the voltage VPGM by the voltage generation circuit VG_pgm. The control circuit 21 controls the timing of outputting the read voltage VCGR by the voltage generation circuit VG_cgr. The control circuit 21 controls the timing of outputting the voltage VREAD by the voltage generation circuit VG_read1. The control circuit 21 controls the timing of outputting the voltage VREAD by the voltage generation circuit VG_read2. The control circuit 21 controls the timing of outputting the voltage VSG by the voltage generation circuit VG_sgs.

The driver 15 can include a further voltage generation circuit. The further voltage generation circuit generates a voltage other than the voltage VSG, the program voltage VPGM, and the read voltage VCGR that are used for data reading, data writing, and data erasing. An example of such a voltage includes a voltage VPASS. The voltage VPASS is supplied to the driver circuits CGIdr_0 to CGIdr_n−1. The driver circuits CGIdr_0 to CGIdr_n−1 transfer the voltage VPASS to the wires CGI_0 to CGI_n−1, respectively.

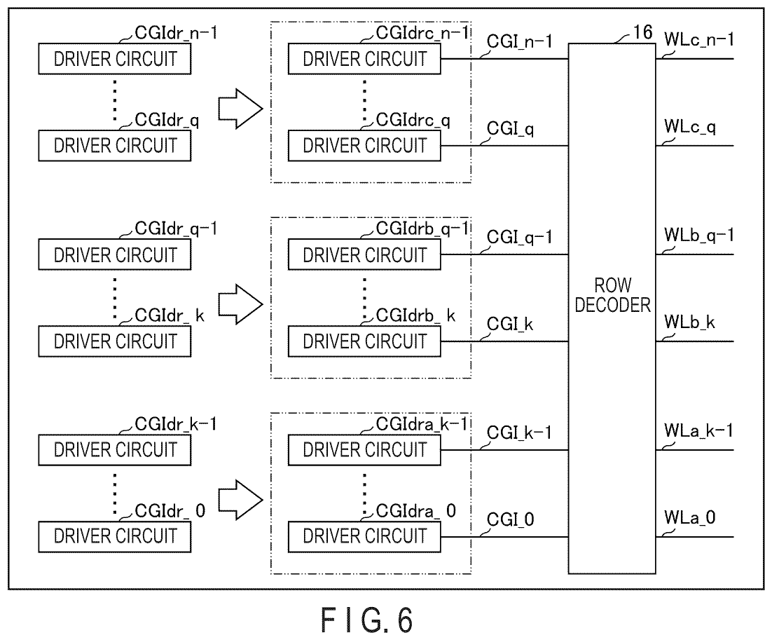

FIG. 6 illustrates classification of the driver circuit in the storage device in the first embodiment. As illustrated in FIG. 6, the driver circuits CGIdr_0 to CGIdr_n−1 are divided into three sets. A first set includes the driver circuits CGIdr_0 to CGIdr_k−1. k is an integer less than n−1. A second set includes the driver circuits CGIdr_k to CGIdr_q−1. q is an integer greater than k and less than n−1. A third set includes the driver circuits CGIdr_q to CGIdr_n−1.

In other words, the first set includes the driver circuit CGIdr connected to a plurality of word lines WL closest to the select gate line SGSL. The third set includes the driver circuit CGIdr connected to a plurality of word lines WL closest to the select gate line SGDL. The second set includes the driver circuit CGIdr connected to the word line WL that is located between the word line WL connected to the first set of the driver circuit CGIdr and the word line WL connected to the third set of the driver circuit CGIdr.

Hereinafter, the driver circuit CGIdr included in the first set may be referred to as the driver circuit CGIdra. The driver circuit CGIdr included in the second set may be referred to as the driver circuit CGIdrb. The driver circuit CGIdr included in the third set may be referred to as the driver circuit CGIdrc.

The driver circuits CGIdra_0 to CGIdra_k−1 are connected to the wires CGI_0 to CGI_k−1, respectively. The driver circuits CGIdrb_k to CGIdrb_q−1 are connected to the wires CGI_k to CGI_q−1, respectively. The driver circuits CGIdrc_q to CGIdrc_n−1 are connected to the wires CGI_q to CGI_n−1, respectively.

The word lines WL connected to the wires CGI via the row decoder 16 (more specifically, the transistors XS in the row decoder 16) may be referred to as the word lines WLa, WLb, or WLc, respectively. The wires CGI_0 to CGI_k−1 are connected to word lines WLa_0 to WLa_k−1 via the row decoder 16, respectively. The wires CGI_k to CGI_q−1 are connected to word lines WLb_k to WLb_q−1 via the row decoder 16, respectively. The wires CGI_q to CGI_n−1 are connected to word lines WLc_q to WLc_n−1 via the row decoder 16, respectively.

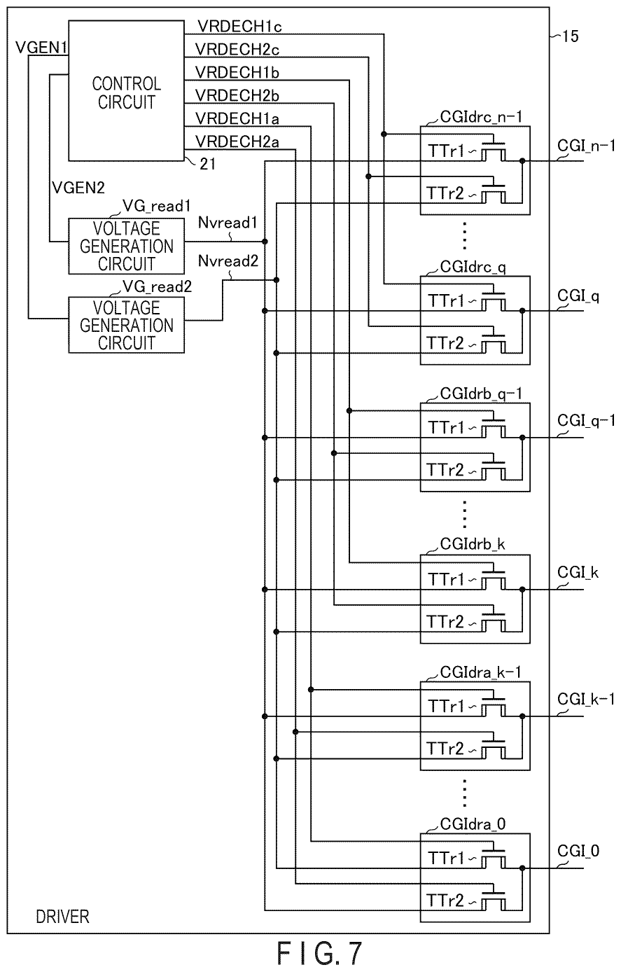

FIG. 7 illustrates components of a part of the driver of the storage device in the first embodiment and connection between the components. FIG. 7 only illustrates the voltage generation circuits VG_read1 and VG_read2, the driver circuits CGIdr (CGIdra, CGIdrb, and CGIdrc), and the control circuit 21.

Each of the driver circuits CGIdra, CGIdrb, and CGIdrc includes transistors TTr1 and TTr2.

Each transistor TTr1 of the driver circuits CGIdra is connected between the wire Nvread1 and one of the wires CGI_0 to CGI_k−1. Each transistor TTr1 of the driver circuits CGIdra receives a voltage VRDECH1a at its gate. The voltage VRDECH1a has a magnitude that enables the transistor TTr1 to transfer the potential of the first end, that is, the voltage Vread received at the first end, to the second end. The voltage VRDECH1a is supplied from the control circuit 21.

Each transistor TTr2 of the driver circuits CGIdra is connected between the wire Nvread2 and one of the wires CGI_0 to CGI_k−1. Each transistor TTr2 of the driver circuits CGIdra receives a voltage VRDECH2a at its gate. The voltage VRDECH2a has a magnitude that enables the transistor TTr2 to transfer the potential of the first end, that is, the voltage Vread received at the first end, to the second end. The voltage VRDECH2a is supplied from the control circuit 21.

Each transistor TTr1 of the driver circuits CGIdrb is connected between the wire Nvread1 and one of the wires CGI_k to CGI_q−1. Each transistor TTr1 of the driver circuits CGIdrb receives a voltage VRDECH1b at its gate. The voltage VRDECH1b has a magnitude that enables the transistor TTr1 to transfer the potential of the first end, that is, the voltage Vread received at the first end, to the second end. The voltage VRDECH1b is supplied from the control circuit 21.

Each transistor TTr2 of the driver circuits CGIdrb is connected between the wire Nvread2 and one of the wires CGI_k to CGI_q−1. Each transistor TTr2 of the driver circuits CGIdrb receives a voltage VRDECH2b at its gate. The voltage VRDECH2b has a magnitude that enables the transistor TTr2 to transfer the potential of the first end, that is, the voltage Vread received at the first end, to the second end. The voltage VRDECH2b is supplied from the control circuit 21.

Each transistor TTr1 of the driver circuits CGIdrc is connected between the wire Nvread1 and one of the wires CGI_q to CGI_n−1. Each transistor TTr1 of the driver circuits CGIdrc receives a voltage VRDECH1c at its gate. The voltage VRDECH1c has a magnitude that enables the transistor TTr1 to transfer the potential of the first end, that is, the voltage Vread received at the first end, to the second end. The voltage VRDECH1c is supplied from the control circuit 21.

Each transistor TTr2 of the driver circuits CGIdrc is connected between the wire Nvread2 and one of the wires CGI_q to CGI_n−1. Each transistor TTr2 of the driver circuits CGIdrc receives a voltage VRDECH2c at its gate. The voltage VRDECH2c has a magnitude that enables the transistor TTr2 to transfer the potential of the first end, that is, the voltage Vread received at the first end, to the second end. The voltage VRDECH2c is supplied from the control circuit 21.

The control circuit 21 supplies an enable signal VGEN1 to the voltage generation circuit VG_read1. The voltage generation circuit VG_read1 operates while receiving the valid logic enable signal VGEN1, that is, applies the voltage Vread to the wire Nvread1.

The control circuit 21 supplies an enable signal VGEN2 to the voltage generation circuit VG_read2. The voltage generation circuit VG_read2 operates while receiving the valid logic enable signal VGEN2, that is, applies the voltage Vread to the wire Nvread2.

### 1.2. Operation

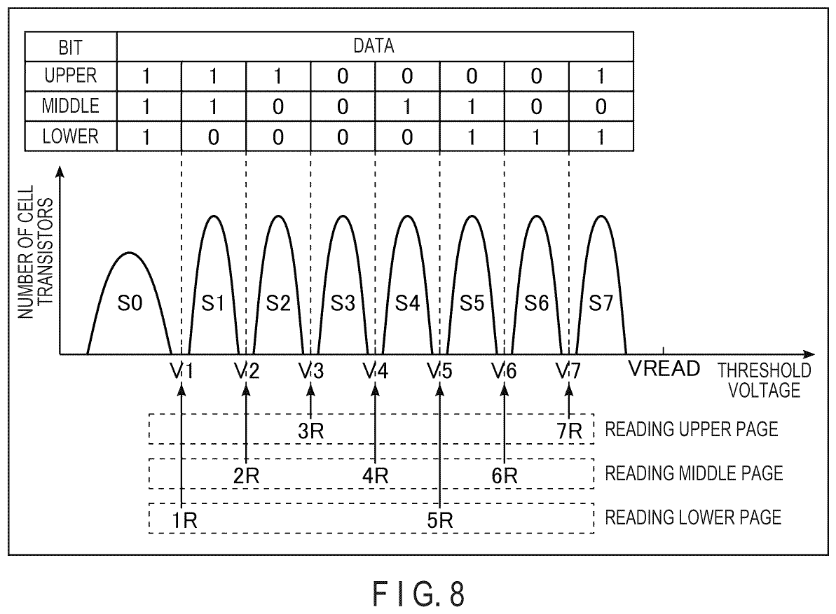

The storage device 1 can store two or more bits of data in one cell transistor MT. FIG. 8 illustrates distribution of threshold voltages of cell transistors storing 3-bit data of the storage device in the first embodiment and an example of mapping of data. The threshold voltage of each cell transistor MT has a magnitude according to the stored data, based on the amount of electrons in its charge storage film CA. In the case of 3-bit memory, each cell transistor MT is in one state of “S0”, “S1”, “S2”, “S3”, “S4”, “S5”, “S6”, and “S7” states according to the threshold voltage. The cell transistor MT in the “S0”, “S1”, “S2”, “S3”, “S4”, “S5”, “S6”, and “S7” states has higher threshold voltages in this order. The cell transistor MT transitions to the “S0” state when the threshold voltage is decreased by data erasing.

By data writing, the cell transistor MT to be written is maintained in the “S0” state, or transitions to one of the “S1”, “S2”, “S3”, “S4”, “S5”, “S6” and “S7” states based on the data to be written. Even a plurality of cell transistors MT that store the same 3-bit data may have threshold voltages that are different from each other. A collection of threshold voltages in one certain state is referred to as a threshold voltage robe.

3-bit data can be assigned to each state in any form. In an example, each state is treated as having the following 3-bit data. In “αβγ” of the following description, α, β, and γ indicate the values of an upper bit, a middle bit, and a lower bit, respectively.
“S0” state: “111”
“S1” state: “110”
“S2” state: “100”
“S3” state: “000”
“S4” state: “010”
“S5” state: “011”
“S6” state: “001”
“S7” state: “101”

Data reading is based on determination of the state by the cell transistor MT to be read. A plurality of read voltages VCGR having different magnitudes are used for determination of the state. When the cell transistor MT has a threshold voltage equal to or more than the read voltage VCGR, the cell transistor MT is OFF even if the read voltage VCGR is received at the control gate electrode, and when the cell transistor MT has a threshold voltage less than the read voltage VCGR, the cell transistor MT is ON when the read voltage VCGR is received at the control gate electrode. Based on this, it is determined whether the threshold voltage of the cell transistor MT to be read is more than the read voltage VCGR.

Determination of whether the cell transistor MT to be read is in a state higher than the “S0”, “S1”, “S2”, “S3”, “S4”, “S5”, “S6”, and “S7” states is performed by using read voltages V1, V2, V3, V4, V5, V6, and V7, respectively. The read voltages V1, V2, V3, V4, V5, V6, and V7 are higher in this order. Obtaining (data reading) a set of bits that indicates whether the cell transistor MT is turned on or off by applying the read voltages V1, V2, V3, V4, V5, V6, and V7 is called 1R, 2R, 3R, 4R, 5R, 6R, and 7R, respectively.

A set of bit data at the same position (digit) of the cell transistor MT of one cell unit CU constitutes one page. A set (or bit sequence) of the least significant bit (the first bit from the bottom) (lower bit) of the cell transistor MT of each cell unit CU is referred to as a lower page. A set (or bit sequence) of the second least significant bit (middle bit) of the cell transistor MT of each cell unit CU is referred to as a middle page. A set (or bit sequence) of the third least significant bit (upper bit) of the cell transistor MT of each cell unit CU is referred to as an upper page.

1R and 5R are used for reading the lower page. The data of the lower page can be determined by 1R and 5R.

2R, 4R, and 6R are used for reading the middle page. The data of the middle page can be determined by 2R, 4R, and 6R.

3R and 7R are used for reading the upper page. The data of the upper page can be determined by 3R and 7R.

The voltage VREAD has a magnitude that turns ON the cell transistor MT, regardless of the state to which the cell transistor MT belongs.

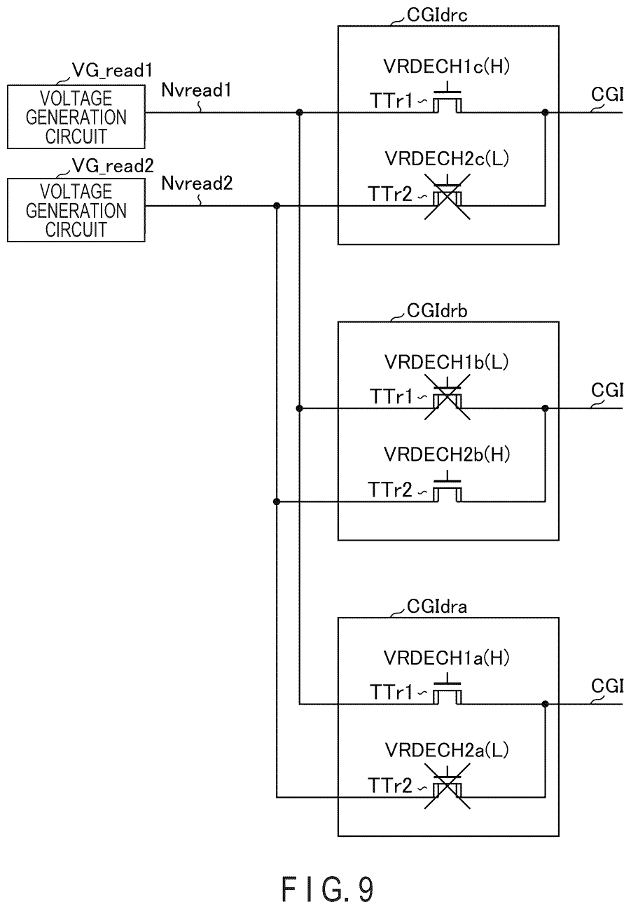

FIG. 9 illustrates one state of the driver during data reading of the storage device in the first embodiment. As illustrated in FIG. 9, the transistor TTr1 of the driver circuit CGIdra is receiving the voltage VREDCH1a at its gate. In addition, the transistor TTr2 of the driver circuit CGIdra is receiving the voltage VREDCH2a at its gate. Therefore, the driver circuit CGIdra is in a state in which the potential of the wire Nvread1 can be transferred to the wire CGI. Hereinafter, when a certain transistor is in a state of receiving, at its gate, a voltage with a magnitude that enables the transistor to transfer the potential at the first end to the second end, the transistor is referred to be ON. A state in which a voltage is applied to the ON-transistor may be referred to as the voltage having a high level (H). On the other hand, when a certain transistor is in a state of not receiving, at its gate, a voltage with a magnitude that enables the transistor to transfer the potential at the first end to the second end, the transistor is referred to be OFF. A state in which a voltage is not applied to the OFF-transistor may be referred to as the voltage having a low level (L).

The transistor TTr1 of the driver circuit CGIdrb is receiving the low-level voltage VREDCH1b at its gate. In addition, the transistor TTr2 of the driver circuit CGIdrb is receiving the high-level voltage VREDCH2b at its gate. Therefore, the driver circuit CGIdrb is in a state in which the potential of the wire Nvread2 can be transferred to the wire CGI.

The transistor TTr1 of the driver circuit CGIdrc is receiving the high-level voltage VREDCH1c at its gate. In addition, the transistor TTr2 of the driver circuit CGIdrc is receiving the low-level voltage VREDCH2c at its gate. Therefore, the driver circuit CGIdrc is in a state in which the potential of the wire Nvread1 can be transferred to the wire CGI.

In this manner, in each of the driver circuits CGIdra, CGIdrb, and CGIdrc, one of the transistors TTr1 and TTr2 is maintained to be ON, and the other is maintained to be OFF.

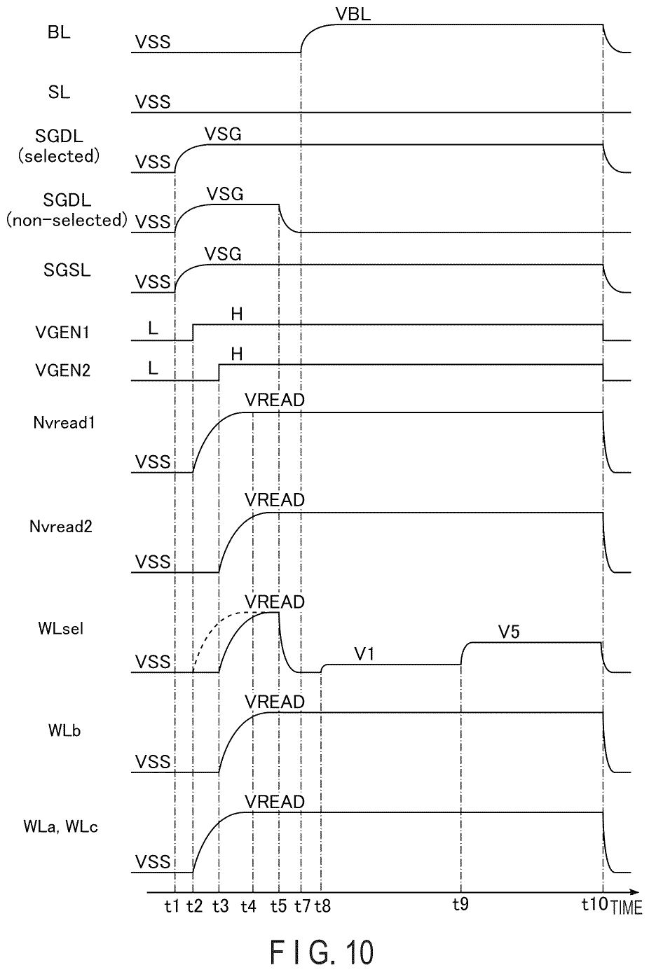

FIG. 10 illustrates the potential of some wires during data reading of the storage device in the first embodiment along a time axis. The operations described below with reference to FIG. 10 occur irrespective of a page from which data is to be read. FIG. 10 illustrates data reading from a lower page as an example. In addition, FIG. 10 illustrates the block BLK including the cell unit CU from which data is to be read. Hereinafter, the cell unit CU from which data is to be read may be referred to as the selected cell unit CUsel. The word line WL connected to the cell unit CU from which data is to be read may be referred to as the selected word line WLsel. The selected word line WLsel may be any of the word lines WLa, WLb, and WLc. The word lines WL other than the selected word line WLsel may be referred to as the non-selected word line WL. The string unit SU including the selected cell unit CU may be referred to as the selected string unit SUsel. The string units SU other than the selected string unit SUsel may be referred to as the non-selected string unit SU.

At the start of the period illustrated in FIG. 10, each of the wires and signals has the following potential or level. A ground voltage VSS is applied to the bit line BL, the source line SL, and the select gate line SGSL, and therefore have a ground potential Vss. The ground potential Vss is a potential that a wire has by receiving the ground voltage VSS. The ground voltage VSS is applied to the select gate line SGDL that is selected and the (non-selected) select gate line SGDL that is not selected, and therefore have the ground potential Vss. The select gate line SGDL that is selected is the select gate line SGDL connected to the selected string unit SUsel. The non-selected select gate line SGDL is the select gate line SGDL connected to the string unit SU other than the selected string unit SUsel.

The enable signals VGEN1 and VGEN2 have a low level. Therefore, the voltage generation circuits VG_read1 and VG_read2 do not operate, and therefore, the wires Nvread1 and Nvread2 have the ground potential VSS. The ground voltage VSS word is applied to the lines WLa, WLb, and WLc and the selected word line WLsel, and therefore have the ground potential VSS.

FIG. 10 illustrates a case where the selected word line WLsel is the word line WLb by a solid line. FIG. 10 illustrates a case where the selected word line WLsel is the word line WLa or WLc by a broken line.

The period from time t1 to time t5 is a preparation period of for data reading.

At time t1, the voltage VSG is applied to the selected select gate line SGDL, the non-selected select gate line SGDL, and the select gate line SGSL. Accordingly, the potentials of the selected select gate line SGDL, the non-selected select gate line SGDL, and the select gate line SGSL are the potential VSG, and therefore, the select gate transistors DT and ST are turned ON.

At time t2, the enable signal VGEN1 is at the high level. Accordingly, the voltage generation circuit VG_read1 starts operation. When the operation is started, the potential of the wire Nvread1 is increased to have a potential VREAD at time t4. The potential VREAD is a potential that the wire has by receiving the voltage VREAD.

As the potential of the wire Nvread1 starts to be increased, the potentials of the word lines WLa and WLc are increased from time t2 to have the potential VREAD at time t4.

At time t3, the enable signal VGEN2 is at the high level. Accordingly, the voltage generation circuit VG_read2 starts operation. When the operation is started, the potential of the wire Nvread2 is increased to have the potential VREAD at time t5. The voltage generation circuit VG_read1 starts operation after the operation of the voltage generation circuit VG_read2 is started. Therefore, the wire Nvread1 has the potential VREAD before the wire Nvread2. As the potential of the wire Nvread2 starts to be increased, the potential of the word line WLb is increased from time t3 to have the potential VREAD at time t5.

From time t1 to time t5, the driver 15 has the state illustrated in FIG. 9.

At time t5, the potential of the selected word line WLsel is the ground potential VSS. This is performed by disconnecting the voltage generation circuit VG_read2 and the wire CGI by the driver circuit CGIdrb connected to the selected word line WLsel, and connecting a node receiving the ground voltage VSS to the wire CGI.

At time t5, the potential of the non-selected select gate line SGDL is the ground potential VSS.

The period after time t7 is a period for actual data reading. After time t7, the source line SL continues to be maintained at the ground potential VSS. The potential of the source line SL may be maintained at a potential slightly higher than the ground potential VSS. From time t7, the potential of the bit line BL is a potential VBL. The potential VBL is higher than the ground potential VSS.

From time t8, the read voltage VCGR is applied that has a magnitude based on a page from which data is to be read in the selected cell unit CUsel. When based on an example of data reading from a lower page as in a present manner, the potential of the selected word line WLsel is a potential V1 at time t8. The potential V1 is a potential that a wire has when the read voltage V1 is applied to the wire.

At time t9, the potential of the selected word line WLsel is a potential V5. The potential V5 is a potential that a wire has when the read voltage V5 is applied to the wire.

Time t10 is the timing for ending the potential to the select gate lines SGDL and SGSL and the word line WL for reading data from the selected cell unit CUsel. That is, the operation at time t10 occurs with the end of application of the read voltage VCGR that is determined based on a page from which data is to be read. When based on an example of reading a lower page, the operation at time t10 occurs with the end of application of the voltages V1 and V5. At time t10, the potentials of the select gate line SGDL connected to the selected string unit SUsel, the select gate line SGSL, and the bit line BL are the ground potential VSS.

At time t10, the enable signal VGEN1 is at the low level. Accordingly, the potential of the wire Nvread1 becomes the ground potential VSS, and the potentials of the word lines WLa and WLc become the ground potential VSS.

At time t10, the enable signal VGEN2 is at the low level. Accordingly, the potential of the wire Nvread2 becomes the ground potential VSS, and the potential of the word line WLb becomes the ground potential VSS.

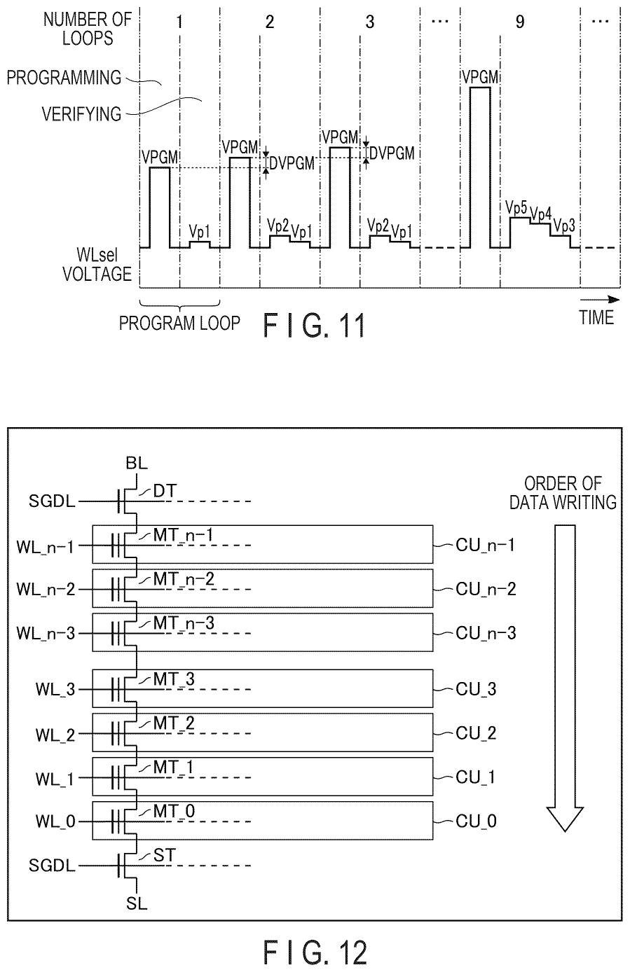

The operation of the storage device 1 can also be applied to verifying that is performed during data writing. FIG. 11 illustrates an overview of a write operation in the storage device in the first embodiment along a time axis. As illustrated in FIG. 11, the storage device 1 repeatedly performs a program loop during a write operation. Each program loop includes programming and verifying.

Programming is an operation for increasing the threshold voltage of the cell transistor MT to which data is to be written. When writing data, the cell transistor MT to which data is to be written may be referred to as the selected cell transistor MTsel. During programming, the selected cell transistor MTsel is set to a program state or a program inhibited state. Whether each selected cell transistor MTsel is set to the program state or the program inhibited state depends on a target state of the selected cell transistor MTsel. The target state is a state to which each selection cell transistor MTsel transitions based on data to be written. When the selected cell transistor MTsel has a threshold voltage less than a voltage that is determined to be included in the target state, the selected cell transistor MTsel is set to the program state. When the selected cell transistor MTsel has a threshold voltage equal to or more than the voltage that is determined to be included in the target state, the selected cell transistor MTsel is set to the program inhibited state.

During programming, the program voltages VPGM of various magnitudes are applied to the selected word line WLsel.

The program voltage VPGM is increased each time the number of loops is increased. When the program voltage VPGM is applied to the selected word line WLsel, the threshold voltage of the selected cell transistor MTsel in the program state is increased. The increase in the threshold voltage of the selected cell transistor MTsel in the program inhibited state is suppressed.

Verifying is an operation for confirming whether the threshold voltage of the selected cell transistor MTsel has a threshold voltage equal to or more than a voltage that is determined to be included in the target state, and is data reading. Hereinafter, a description of “data reading” is used as a term referring to an operation that includes verifying. In verifying, it is determined whether the threshold voltage of the selected cell transistor MTsel is equal to or more than a verify voltage Vp having a variable magnitude. The sense amplifier 17 outputs data based on whether the threshold voltage of each selected cell transistor MTsel is equal to or more than the verify voltage Vp. When the threshold voltage of the selected cell transistor MTsel is equal to or more than the verify voltage Vp, the data indicating that the threshold voltage has passed verifying is output. The verify voltage Vp has a magnitude that depends on a target state, and is lower than a threshold voltage that the selected cell transistor MTsel considered to have transitioned to the target state should minimally have. In an example, the verify voltages Vp1, Vp2, Vp3, Vp4, Vp5, Vp6, and Vp7 for each of the “S0”, “S1”, “S2”, “S3””, “S4” , “S5”, “S6”, and “S7” states are the same as the read voltages V1, V2, V3, V4, V5, V6, and V7, respectively. In another example, the verify voltages Vp1, Vp2, Vp3, Vp4, Vp5, Vp6, and Vp7 are slightly lower than the read voltages V1, V2, V3, V4, V5, V6, and V7 respectively.

FIG. 12 illustrates the order of data writing in the storage device in the first embodiment. As illustrated in FIG. 12, in data writing, writing is performed in the order from the cell unit CU closer to the bit line BL to the cell unit CU closer to the source line SL. That is, data is written earlier to the cell units CU closer to the bit line BL. The cell transistors MT of the cell unit CU to which data has not been written is in an erased state, that is, the “S0” state.

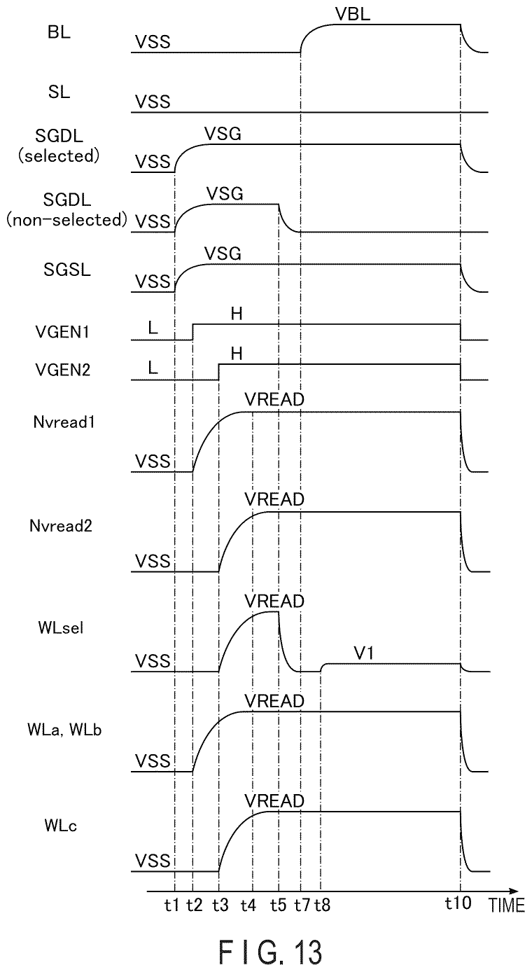

FIG. 13 to FIG. 15 illustrate the potentials of some nodes during verifying in the storage device in the first embodiment along a time axis.

FIG. 13 illustrates data writing to the cell units CU that belong to the third set. The third set includes the cell units CU connected to the word line WLc. That is, the third set consists of the cell unit CU_q to the cell unit CU_n−1. The cell unit CU_q to the cell unit CU_n−1 are cell units CU that are connected to the word lines WLc_q to WLc_n−1, respectively, and that are connected to the driver circuit CGIdrc of the third set. During verifying illustrated in FIG. 13, by control similar to the control described above with reference to FIG. 9, each of the driver circuit CGIdra and CGIdrb is in a state in which the potential of the wire Nvread1 can be transferred to the wire CGI to which it is connected. On the other hand, during verifying illustrated in FIG. 13, by control similar to the control described above with reference to FIG. 9, the driver circuit CGIdrc is in a state in which the potential of the wire N vread2 can be transferred to the wire CGI to which it is connected.

The waveforms illustrated in FIG. 13 are different from the waveforms illustrated in FIG. 10 in that the word lines WL the potentials of which are set to the potential VREAD are different. As illustrated in FIG. 13, as the potential of the wire Nvread1 starts to be increased from time t2, the potentials of the word lines WLa and WLb are increased from time t2 to have the potential VREAD. As the potential of the wire Nvread2 starts to be increased from time t3, the potential of the word line WLc is increased from time t3 to have the potential VREAD.

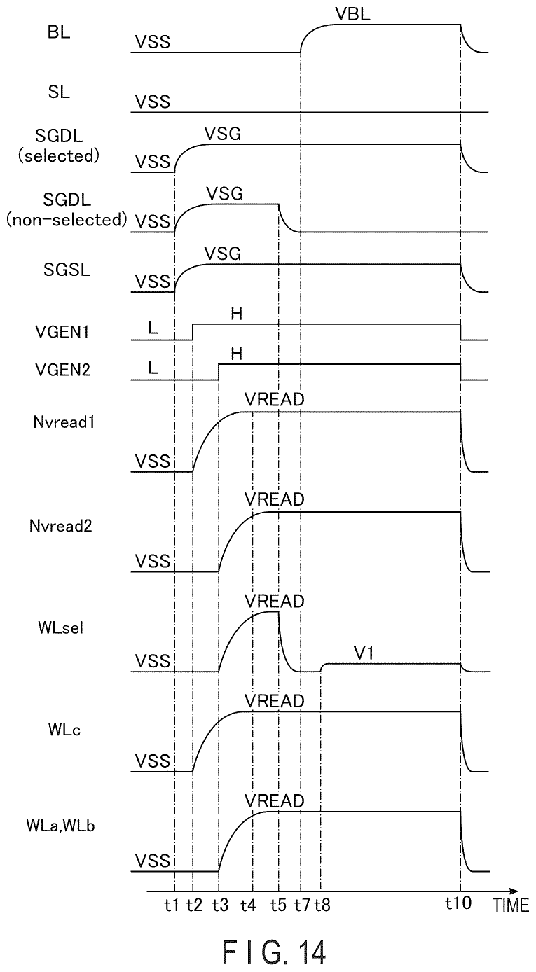

FIG. 14 illustrates data writing to the cell units CU that belong to the second set. The second set consists of the cell units CU connected to the word line WLb. That is, the second set consists of the cell unit CU_k to the cell unit CU_q−1. The cell unit CU_k to the cell unit CU_q−1 are cell units CU that are connected to the word lines WLb_k to WLb_q−1, respectively, and that are connected to the driver circuit CGIdrb of the second set. During verifying illustrated in FIG. 14, by control similar to the control described above with reference to FIG. 9, the driver circuit CGIdrc is in a state in which the potential of the wire Nvread1 can be transferred to the wire CGI to which it is connected. On the other hand, during verifying illustrated in FIG. 14, by control similar to the control described above with reference to FIG. 9, each of the driver circuits CGIdra and CGIdrb is in a state in which the potential of the wire Nvread2 can be transferred to the wire CGI to which it is connected.

The waveforms illustrated in FIG. 14 are different from the waveforms illustrated in FIG. 10 in that the word lines WL the potentials of which are set to the potential VREAD are different. As illustrated in FIG. 14, as the potential of the wire Nvread1 starts to be increased from time t2, the potential of the word line WLc is increased from time t2 to have the potential VREAD. As the potential of the wire Nvread2 starts to be increased from time t3, the potentials of the word lines WLa and WLb are increased from time t3 to have the potential VREAD.

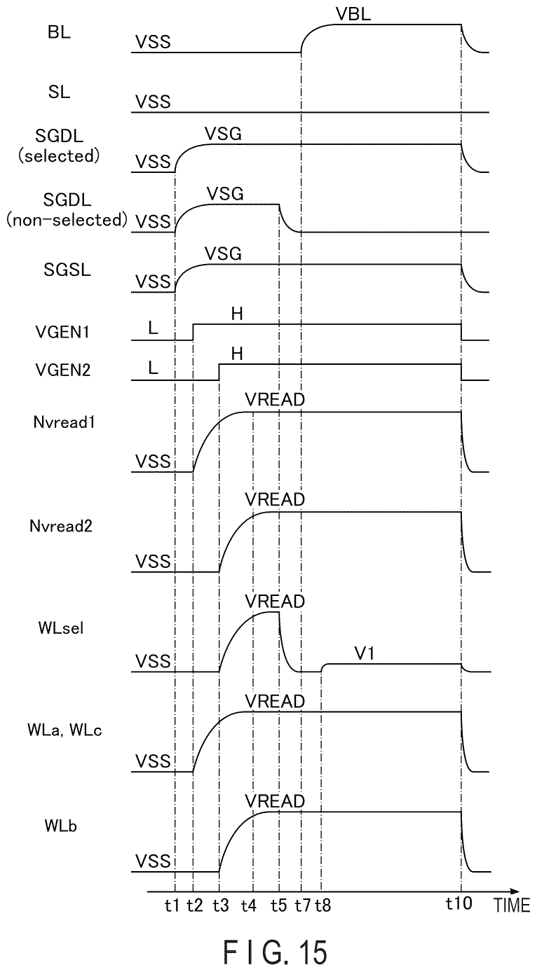

FIG. 15 illustrates data writing to the cell units CU that belong to the first set. The 1st set consists of the cell units CU connected to the word line WLa. That is, the first set consists of the cell unit CU_0 to the cell unit CU_k−1. The cell units CU_0 to the cell unit CU_k−1 are cell units CU that are connected to the word lines WLa_0 to WLa_k−1, respectively, and that are connected to the driver circuit CGIdra of the first set. During verifying illustrated in FIG. 15, by control similar to the control described above with reference to FIG. 9, each of the driver circuits CGIdra and CGIdrc is in a state in which the potential of the wire Nvread1 can be transferred to the wire CGI to which it is connected. On the other hand, during verifying illustrated in FIG. 15, by control similar to the control described above with reference to FIG. 9, the driver circuit CGIdrb is in a state in which the potential of the wire Nvread2 can be transferred to the wire CGI to which it is connected.

The waveforms illustrated in FIG. 15 are different from the waveforms illustrated in FIG. 10 in that the word lines WL the potentials of which are set to the potential VREAD are different. As illustrated in FIG. 15, as the potential of the wire Nvread1 starts to be increased from time t2, the potentials of the word lines WLa and WLc are increased from time t2 to have the potential VREAD. As the potential of the wire Nvread2 starts to be increased from time t3, the potential of the word line WLb is increased from time t3 to have the potential VREAD.

### 1.3. Advantages (Effects)

According to the first embodiment, a storage device capable of reading data at high speed is provided as described below.

In a storage device such as the storage device 1, when application of a voltage to a wire for data reading is started (hereinafter may be referred to as the initial stage of data reading), there are cases in which all the string units SU in the block BLK including at least the selected cell unit CU are connected to the bit line BL and (or) the source line SL. For this purpose, setting of the potentials of the wires as described below is performed. That is, in addition to that the potentials of the select gate line SGSL and the selected select gate line SGDL are set to the potential VSG over a period of data reading, the potential of the select gate line SGDL of the non-selected string unit SU is also set to the potential VSG in the initial stage of data reading. Furthermore, in the initial stage of data reading, the voltage VREAD is temporarily applied to the selected word line WLsel in addition to the non-selected word line WL. In this manner, the cell transistor MT is turned ON, and the channel of the cell transistor MT is formed, and thus the channel of each cell transistor MT is connected to the bit line BL and the source line SL via the channels of the other cell transistor MT. Accordingly, read disturb due to hot carrier formation during data reading is suppressed. Hereinafter, the operation of turning ON the select gate transistor DT of the non-selected string unit SU in the initial stage of data reading may be referred to as the non-selected string discharging operation.

During the non-selected string discharging operation, the lower the threshold voltage of the cell transistor MT, the faster the cell transistor MT is turned ON. Therefore, the channel region of the cell transistor MT sandwiched between cell transistors MT that are still OFF is in a state in which the cell transistor MT is boosted (has a high potential) by capacitive coupling with the word line WL having the potential VREAD. Thus, the capacitance of the channel regions of the cell transistors MT that are OFF do not function as the load capacitance of the word lines WL connected to these cell transistors MT that are OFF. As the number of cell transistors MT that are ON is increased over time, the number of word lines WL to which the capacitance of the channel region is added is increased with the boosting of the channel region ends.

In addition, when the cell transistor MT is turned ON, the channel region of the adjacent cell transistor MT connected to this turned-ON cell transistor MT is connected to the turned-ON cell transistor MT. At this time, the boosting of the channel region of the adjacent cell transistor MT is released. When the turned-ON cell transistor MT is already connected to the bit line BL or the source line SL and thus has the ground potential VSS, the potential of the channel region of the adjacent cell transistor MT is decreased toward the ground potential VSS. At this time, since the word line WL and the channel region are capacitively coupled in the adjacent cell transistor MT, the potential of the word line WL of the adjacent cell transistor MT is decreased. This prevents charging of the word line WL, and thus increases the time required for data reading.

On the other hand, the non-selected string discharging operation in the block BLK to which data has not been written is different from the non-selected string discharging operation in the block BLK to which data has been written. Hereinafter, the block BLK that includes the cell unit CU to which data has been written may be referred to as the closed block, and the block BLK that does not include the cell unit CU to which data has been written (that is, in an erased state) may be referred to as the open block. In an initial stage of the non-selected string discharging operation, the open block does not have a channel region in which channel boosting is performed in the non-selected string discharging operation as in the closed block. Therefore, in the initial stage, due to existence of the load capacity to the word line WL, the increase in the potential of the word line WL in the open block is slower than the increase in the potential of the word line WL in the closed block. On the other hand, after the initial stage of the non-selected string discharging operation, as described above, while the potential of the word line WL is decreased due to the end of the boosting of the channel region of the newly turned-ON cell transistor MT, such a situation does not occur in the open block. Therefore, after the initial stage of the non-selected string discharging operation, the speed of charging of the word line WL in the open block is fast. Therefore, in the open block, the charging speed of the word line WL is slow in the initial stage, but eventually, charging of the word line WL is completed at a timing earlier than the completion of charging of the word line WL in the closed block.

In order to increase the speed of charging of the word line WL, it is conceivable to increase the capability of the voltage generation circuits. However, since the storage device includes a large number of blocks BLK and string units SU in order to realize a large storage capacity of the storage device, when the capability of the voltage generation circuits is increased, a peak current becomes larger. As a result, since the peak current may exceed an upper limit, the capability of the voltage generation circuits cannot be increased.

According to the first embodiment, application of the voltage VREAD to the word lines WL closer to the bit line BL and the source line SL is started before application of the voltage VREAD to the word lines WL farther from both the bit line BL and the source line SL. Therefore, the word lines WL closer to the bit line BL and the source line SL come to have the potential VREAD earlier than the word lines WL farther from both the bit line BL and the source line SL. Therefore, the cell transistors MT closer to the bit line BL and the source line SL are turned ON in the initial stage of the non-selected string discharging operation. This leads to turning ON of many cell transistors MT in the initial stage of the non-selected string discharging operation, and forms a situation similar to the situation formed in the open block. Therefore, charging of the word lines WL becomes faster. In addition, since many cell transistors MT are turned ON in the initial stage of the non-selected string discharging operation, there are few cell transistors MT that include the channel regions to be boosted. Thus, the decrease in the potentials of the word lines WL due to the decrease in the potentials of the channel regions that are boosted when the cell transistors MT are turned ON is suppressed. This results in suppression of the current consumption of the storage device 1.

According to the first embodiment, during verifying, application of the voltage VREAD to the word lines WL closer to the bit line BL and the source line SL or the word lines WL connected to the cell unit CU to which data has not been written is started before application of the voltage VREAD to the selected word line WL. Accordingly, by the same principles as described above for data reading, in the initial stage of the non-selected string discharging operation, a situation similar to the situation formed in the open block is formed. Therefore, charging of the word lines WL becomes faster, and the current consumption of the storage device 1 is suppressed.

### 1.4. Modifications

During data reading, only one of the driver circuits CGIdra and CGIdrb may output the voltage VREAD first. That is, one of the driver circuits CGIdra or CGIdrb may be subjected to the same control as the driver circuit CGIdrb.

In data writing, writing may be performed in the order from the cell units CU closer to the source line SL to the cell units CU closer to the bit line BL. That is, data is written earlier in the cell units CU closer to the bit line BL. In this case, regarding the word lines WL to which the voltage VREAD is applied first, the description about the word line WLa and the description about the word line WLc that are made with reference to FIG. 13 to FIG. 15 are interchanged.

### 2. Second Embodiment

A second embodiment is different from the first embodiment in that a method of applying the voltage VREAD is different.

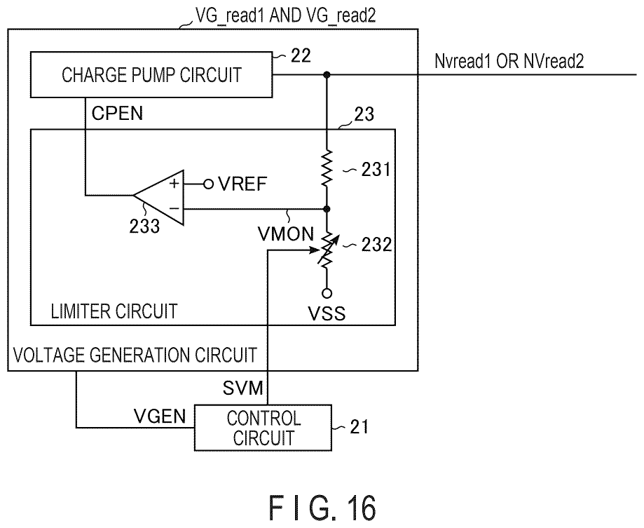

FIG. 16 illustrates the components of a voltage generation circuit of a storage device in a second embodiment and an example of connection. As illustrated in FIG. 16, a voltage generation circuit VG (that is, each of VG_read1 and VG_read2) includes a charge pump circuit 22 and a limiter circuit 23.

The charge pump circuit 22 is a circuit that receives a voltage such as a power supply voltage, and generates a higher voltage from the received voltage. The output of the charge pump circuit 22 functions as a wire Nvread (that is, the wire Nvread1 or Nvread2). The charge pump circuit 22 receives an enable signal CPEN. The charge pump circuit 22 operates while receiving a valid logic enable signal CPEN.

The limiter circuit 23 is a circuit that controls the operation of the charge pump circuit 22 based on the output of the charge pump circuit 22. The limiter circuit 23 includes a resistor 231, a variable resistor circuit 232, and an operational amplifier 233.

The resistor 231 is connected between a node Vread and a node VMON. The resistor 231 has a fixed magnitude.

The variable resistor circuit 232 is connected between the node VMON and a node at the ground potential VSS. The variable resistor circuit 232 receives a control signal SVM. The variable resistor circuit 232 exhibits the resistance with a magnitude based on the value indicated by the control signal SVM. In an example, the control signal SVM includes a plurality of bits. The control signal SVM is supplied from the control circuit 21. The voltage with a magnitude based on the magnitude of the variable resistor circuit 232 is applied to the node VMON.

The operational amplifier 233 receives a reference voltage VREF at a non-inverted input terminal. The operational amplifier 233 is connected to the node VMON at an inverted input terminal. An output terminal of the operational amplifier 233 outputs the enable signal CPEN. While the potential of the node VMON is less than the magnitude of the reference voltage VREF, an asserted enable signal CPEN is output. While the potential of the node VMON is more than the magnitude of the reference voltage VREF, an invalid logic (or negated) signal CPEN is output. By controlling the value of the enable signal CPEN to control the magnitude of the variable resistor circuit 232, the operation and non-operation of the charge pump circuit 22, and thus the increase in the potential of the wire Nvread, can be controlled.

Each of the voltage generation circuits VG_read1 and VG_read2 is enabled by the enable signal VGEN. The enable signal VGEN is supplied from the control circuit 21. The enable signals VGEN1 and VGEN2 may be used, and the enable signals VGEN1 and VGEN2 may have the same logic as in the first embodiment.

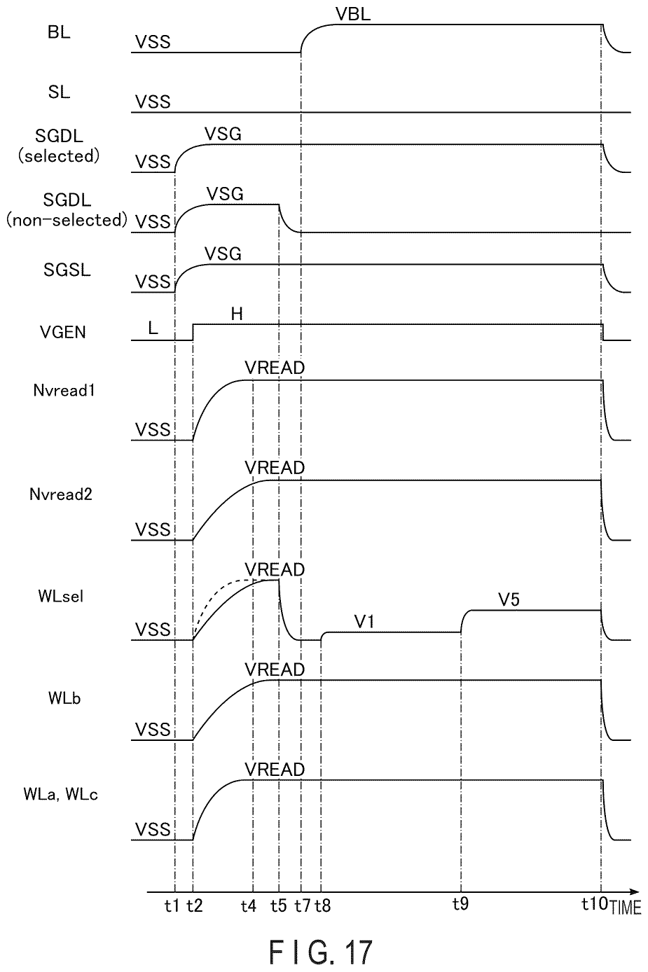

FIG. 17 illustrates the potential of some wires during data reading of the storage device in the second embodiment along a time axis. As illustrated in FIG. 17, at time t2, the enable signal VGEN is at the high level. This causes the voltage generation circuits VG_read1 and VG_read2 to start operating. On the other hand, the control circuit 21 of the driver 15 controls the voltage generation circuits VG_read1 and VG_read2 in different manners. That is, the control circuit 21 starts to increase the potential of the wires Nvread1 and Nvread2 at the same timing and increases the potential at different speeds. The control circuit 21 increases the potential of the wire Nvread1 at a speed faster than the speed of increasing the potential of the wire Nvread2. This is performed by making the value indicated by the control signal SVM supplied to the voltage generation circuit VG_read1 different from the value indicated by the control signal SVM supplied to the voltage generation circuit VG_read2. The value of the control signal SVM may have a constant magnitude or may be changed from time t2 to time t4. Since the increase in the potential of the wire Nvread1 is faster than the increase in the potential of the wire Nvread2, the wire Nvread1 comes to have the potential VREAD at time t4. On the other hand, the wire Nvread2 comes to have the potential VREAD at time t5.

According to the storage device in the second embodiment, the speed at which the voltage VREAD applied to the word lines WL closer to the bit line BL and the source line SL increased is faster than the speed at which the voltage VREAD applied to the word lines WL farther from both the bit line BL and the source line SL is increased. Therefore, as in the first embodiment, the word lines WL closer to the bit line BL and the source line SL come to have the potential VREAD earlier than the word lines WL farther from both the bit line BL and the source line SL. Thus, the same advantages as in the first embodiment can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A storage device comprising:
a bit line;
a source line;
a first cell transistor between the bit line and the source line;
a second cell transistor between the first cell transistor and the bit line;
a third cell transistor between the first cell transistor and the source line;
a first word line connected to a gate of the first cell transistor;
a second word line connected to a gate of the second cell transistor; and
a third word line connected to a gate of the third cell transistor, wherein
a first voltage is applied to the source line over a first period,
a second voltage equal to or more than threshold voltages of the first, second, and third cell transistors is applied to at least one of the second word line and the third word line during the first period to reach the second voltage at a first time in the first period, and
a third voltage equal to or more than the threshold voltages of the first, second, and third cell transistors is applied to the first word line to reach the third voltage at a second time in the first period, the second time being after the first time.

2. The storage device of claim 1, wherein the second voltage is applied at a first initial time and the third voltage is applied at a second initial time, the second initial time being after the first initial time.

3. The storage device of claim 2, further comprising:
a first transistor between the bit line and the second cell transistor; and
a second transistor between the source line and the third cell transistor, wherein
the first transistor and the second transistor are maintained to be ON during the first period.

4. The storage device of claim 3, further comprising:
a fourth cell transistor between the first transistor and the second transistor; and
a fourth word line connected to a gate of the fourth cell transistor, wherein
a fourth voltage lower than the second voltage and the third voltage is applied to the fourth word line at a third time after the first period,
the second voltage is applied to the second word line and the third word line from the first time until the third time or later, and
the third voltage is applied to the first word line from the second time until the third time or later.

5. The storage device of claim 4, wherein
the first transistor and the second transistor are maintained to be ON from the first period to the third time or later.

6. The storage device of claim 5, further comprising:
a fifth cell transistor that is located between the bit line and the source line, and that has a gate connected to the first word line;
a third transistor between the bit line and the fifth cell transistor; and
a fourth transistor between the source line and the fifth cell transistor, wherein
the third transistor and the fourth transistor are maintained to be ON during the first period.

7. The storage device of claim 6, wherein the third transistor is OFF at the third time.

8. The storage device of claim 7, further comprising:
a sixth cell transistor between the fifth cell transistor and the third transistor, and that has a gate connected to the second word line;
a seventh cell transistor between the fifth cell transistor and the fourth transistor, and that has a gate connected to the third word line; and
an eighth cell transistor between the third transistor and the fourth transistor, and that has a gate connected to the fourth word line.

9. The storage device of claim 2, wherein the second voltage is applied to both the second word line and the third word line at the first initial time.

10. The storage device of claim 2, wherein the second voltage and the third voltage are the same.

11. The storage device of claim 1,
wherein the second voltage reaches the second voltage over a second period, and
the third voltage reaches the third voltage over a third period longer than the second period.

12. The storage device of claim 11, further comprising:
a first transistor between the bit line and the second cell transistor; and
a second transistor between the source line and the third cell transistor, wherein
the first transistor and the second transistor are maintained to be ON during the first period.

13. The storage device of claim 12, further comprising:
a fourth cell transistor between the first transistor and the second transistor; and
a fourth word line connected to a gate of the fourth cell transistor, wherein
a fourth voltage lower than the second voltage and the third voltage is applied to the fourth word line at a first time during the first period,
the second voltage is applied to the second word line and the third word line from the first period until the first time or later, and
the third voltage is applied to the first word line from the first period to the first time or later.

14. The storage device of claim 13, wherein
the first transistor and the second transistor are maintained to be ON from the first period to the first time or later.

15. The storage device of claim 14, further comprising:
a fifth cell transistor that is located between the bit line and the source line, and that has a gate connected to the first word line;
a third transistor between the bit line and the fifth cell transistor; and
a fourth transistor between the source line and the fifth cell transistor, wherein
the third transistor and the fourth transistor are maintained to be ON during the first period.

16. The storage device of claim 15, wherein
the third transistor is OFF at the first time.

17. The storage device of claim 16, further comprising:
a sixth cell transistor that is located between the fifth cell transistor and the third transistor, and that has a gate connected to the second word line;
a seventh cell transistor that is located between the fifth cell transistor and the fourth transistor, and that has a gate connected to the third word line; and
an eighth cell transistor that is located between the third transistor and the fourth transistor, and that has a gate connected to the fourth word line.

18. The storage device of claim 11, wherein the first period and the second period have a same start point.

19. The storage device of claim 11, wherein the second voltage is applied to both the second word line and the third word line over the first period.

20. The storage device of claim 11, wherein the second voltage and the third voltage are the same.
